(19) United States
(12) Patent Application Publication
(10) Pub. No.: US 2025/0057054 A1
(43) Pub. Date: Feb. 13, 2025

(54) MATERIAL INTERFACE WITH STABILIZED TIME-REVERSAL SYMMETRY BREAKING FIELD

(71) Applicants: BROWN UNIVERSITY, Providence, RI (US); UNIVERSITAET INNSBRUCK, Innsbruck (AT)

(72) Inventors: Jia Li, Providence, RI (US); Mathias S. Scheurer, Innsbruck (AT); Jiangxiazi Lin, Providence, RI (US); Phum Siriviboon, Providence, RI (US); Erin Morissette, Providence, RI (US)

(21) Appl. No.: 18/718,173

(22) PCT Filed: Dec. 14, 2022
(86) PCT No.: PCT/US2022/052793

§ 371 Date: Jun. 10, 2024

Related U.S. Application Data
(60) Provisional application No. 63/289,563, filed on Dec. 14, 2021.

(51) Int. Cl. H10N 60/10; H10N 60/01; H10N 60/85

(52) U.S. Cl. CPC H10N 60/10; H10N 60/01; H10N 60/85

(57) ABSTRACT

Systems and methods are provided for using a stabilized time-reversal symmetry breaking field to provide a desired function. A structure includes a layer of a first material positioned in contact with a layer of a second material to form an interface between the first material and the second material. Each of the first material and the second material are selected such that a time-reversal symmetry breaking field associated with the interface is stabilized. A control apparatus associated with the structure is configured to control a ferromagnetic state associated with the interface.

### RELATED APPLICATIONS

This application claims priority from U.S. Provisional Patent Application Ser. No. 63/289,563 filed on Dec. 14, 2021, and entitled “Two-Dimensional Material Architecture,” which is hereby incorporated by reference in its entirety.

### GOVERNMENT FUNDING STATEMENT

This invention was made with government support by the Department of Defense (DoD) through the National Defense Science & Engineering Graduate (NDSEG) Fellowship Program. The government has certain rights in the invention.

### TECHNICAL FIELD

The present invention relates to two-dimensional semiconductors, and more particularly, to a material interface with a stabilized time-reversal symmetry breaking field.

### BACKGROUND

In materials science, the terms single-layer materials and two-dimensional materials refer to crystalline solids consisting of a single layer of atoms. Single layers of two-dimensional materials can be combined into layered assemblies. For example, bilayer graphene is a material consisting of two layers of graphene and trilayer graphene is a material formed from three layers of graphene. A two-dimensional semiconductor is a type of natural semiconductor with thicknesses on the atomic scale. Two-dimensional semiconductor materials are often synthesized using a chemical vapor deposition method. They can also be exfoliated from bulk crystals with layered structure. These individual layers are then assembled together to form two-dimensional heterojunctions, which are interfaces between two layers or regions of dissimilar materials.

### SUMMARY OF THE INVENTION

In one aspect of the present invention, an assembly is provided. The assembly includes a structure including a layer of a first material positioned in contact with a layer of a second material to form an interface between the first material and the second material. Each of the first material and the second material are selected such that a time-reversal symmetry breaking field associated with the interface is stabilized. This time-reversal symmetry breaking field is generated spontaneously as a result of the interactions among the electrons on the interface. A control apparatus associated with the structure is configured to control a ferromagnetic state associated with the interface.

In another aspect of the present invention, a method is provided for fabricating an assembly. A first material is positioned in contact with a second material to form a structure with an interface between the first material and the second material. Each of the first material and the second material are selected such that a time-reversal symmetry breaking field is stabilized at the interface. Either a DC current is applied to the interface, an out-of-plane electric field is applied to the interface, a magnetic field is applied to the interface, or a voltage bias is applied to a gate electrode associated with the interface to control a valley ferromagnetic state associated with the interface.

In a further aspect of the present invention, a superconducting diode assembly includes a structure formed as a transition metal dichalcogenide layered on twisted trilayer graphene to form an interface having a stabilized time-reversal symmetry breaking field. A control apparatus associated with the structure is configured to apply a magnetic field to the interface to provide a structure that exhibits superconducting transport behavior when current flows in one direction and exhibits significant resistance when current flows in the opposite direction.

### BRIEF DESCRIPTION OF THE DRAWINGS

FIG. 1 illustrates an assembly that uses a stabilized time-reversal symmetry breaking field to provide a desired function;

FIG. 2 illustrates an example implementation of the system of FIG. 1 utilizing a structure formed from twisted trilayer graphene and a layer of tungsten diselenide;

FIG. 3 illustrates another example implementation of the system of FIG. 1 utilizing a structure formed from twisted trilayer graphene and a layer of tungsten diselenide;

FIG. 4 is a diagram illustrating the behavior of the superconducting diode formed by the structure of FIG. 3 after training with the out-of-plane magnetic field;

FIG. 5 illustrates an example implementation of the system of FIG. 1 utilizing a structure formed from twisted bilayer graphene and a layer of tungsten diselenide;

FIG. 6 illustrates an example of a method 600 for fabricating an assembly that uses a stabilized time-reversal symmetry breaking field to provide a desired function.

### DETAILED DESCRIPTION

As used herein, twisted multi-layer graphene refers to a material formed from multiple layers of graphene in which at least one layer has been rotated, or twisted, at a predetermined angle relative to at least one other layer. It will be appreciated that the predetermined angle need not be an expected magic angle associated with the twisted trilayer graphene, and may be a non-zero angle less than the expected magic angle.

As used herein, a field is out-of-plane for a given plane when the dot product of a vector representing a direction of the field at the plane and a vector normal to the plane is non-zero.

As used herein, a transition metal dichalcogenide is a compound of the type MX2, where M is a transition metal and X a chalcogen (e.g., S, Se, or Te). As used herein, a monolayer of a transition metal dichalcogenide is one-atom thick layer of transitional metal positioned between two one-atom thick layers of the chalcogen.

The critical current of a superconductor can be different for opposite directions of current flow when both time-reversal and inversion symmetry are broken. Such non-reciprocal behavior creates a superconducting diode, and the systems and methods provided herein provide an intrinsic superconducting diode effect that is present at zero external magnetic field in mirror-symmetric twisted trilayer graphene. Such non-reciprocal behavior, with sign that can be reversed through training with an out-of-plane magnetic field, provides direct evidence of the microscopic coexistence between superconductivity and time-reversal symmetry breaking.

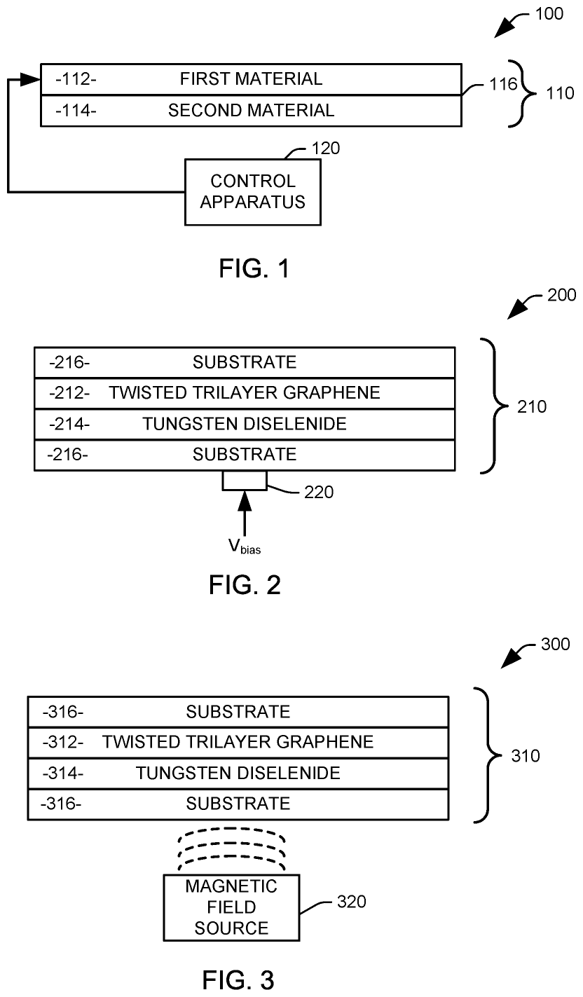

FIG. 1 illustrates an assembly 100 that uses a stabilized time-reversal symmetry breaking field to provide a desired function. The assembly 100 includes a structure 110 with a layer of a first material 112 in contact with a second material 114 to form an interface 116 between the first material and the second material. In accordance with an aspect of the present invention, each of the first material 112 and the second material 114 are selected such that a time-reversal symmetry breaking field associated with the interface is stabilized. In one example, the first material 112 is twisted multi-layer graphene and the second material 114 is a transition metal dichalcogenide, with a valley ferromagnetic state associated being stabilized at the interface 116.

A control apparatus 120 associated with the structure 110 is configured to control a ferromagnetic state associated with the interface 116 and provide the desired function. The control apparatus 120 can include, for example, any of a current source configured to provide a DC current, a voltage source, a gate electrode connected to a voltage source and configured to apply field effect gating to the interface 116, an electric field source configured to apply an out-of-plane electric field to the interface 116, and a magnetic field source configured to apply an out-of-plane magnetic field to the interface 116. It will be appreciated that the control apparatus 120 can include more than one of these structures to provide multiple avenues for controlling the ferromagnetic state and controlling the function of the structure 110.

In one example, the first material 112 is twisted trilayer graphene and the control apparatus 120 is configured to provide a magnetic field that is out of a plane associated with the interface. This magnetic field trains the interface to provide a superconducting diode having a direction of current flow for which superconducting transport behavior is exhibited that is dependent on the direction of the field. It will be appreciated that the superconducting transport behavior is only exhibited for temperatures under a critical temperature (e.g., around one to two kelvin), for a specific range of currents (e.g., less than ten nanoamps), and for a specific range of voltage bias applied to the gate electrode (e.g., the moiré energy band is close to half filled). It does not, however, require application of a magnetic or electric field after the initial training, and the superconducting transport behavior is provided in the absence of any such fields at the interface.

In another example, the first material 112 is twisted trilayer graphene and the control apparatus 120 comprises a gate electrode connected to a voltage source and configured to apply field effect gating to the interface. Depending on the voltage applied to the gate electrode, and thus an associated mode of the field effect doping, the direction of the superconducting transport behavior can be initialized and dynamically controlled. It will be appreciated that these examples are non-exclusive, and that both control mechanisms can be used in initializing the superconducting transport behavior and controlling its direction. In a further example, the first material 112 is twisted bilayer graphene, and the ferromagnetic state is controllable via the control apparatus to store a bit within the structure or read a bit from the structure.

FIG. 2 illustrates an example implementation 200 of the system of FIG. 1 utilizing a structure 210 formed from twisted trilayer graphene 212 and a layer of tungsten diselenide (WSe₂) 214. In the illustrated implementation, each of the twisted trilayer graphene 212 and the layer of tungsten diselenide 214 is layered on and supported by a dielectric substrate 216, such as hexagonal boron nitride (HBN), that has been exfoliated to be atomically flat, such that the twisted trilayer graphene and the layer of tungsten diselenide are substantially encapsulated by the dielectric substrate. At the interface between the twisted trilayer graphene 212 and the layer of tungsten diselenide 214, a stable time-reversal symmetry breaking field associated with the interface is obtained, and a valley ferromagnetic state associated with the interface can be controlled via a gate electrode 220, or more precisely, a voltage applied to the gate electrode, to provide and dynamically control a superconducting diode provided by the structure. Depending on the arrangement, the field effect doping can be applied as to provide a moiré filling fraction between 2 and 3.5. The superconducting phase is realized in the moiré filling fraction range between 2 and 3.5, or −2 and −3.5. It will be appreciated, however, that the initialized diode can function in the superconducting phase in the absence of an applied field effect doping.

In the illustrated implementation, the twisted trilayer graphene 212 is not twisted at the magic angle associated with trilayer graphene. The interplay between Coulomb correlation and superconductivity in the small-twist-angle regime takes a form distinct from the magic angle. In the small-twist-angle regime, a lack of hierarchy between the correlation-driven phases indicates that the influence of flavor polarization is substantially diminished. This provides a partial imbalance in the valley occupation of the underlying Fermi surface, which assists in realizing the zero-field superconducting diode effect. Partial valley polarization is unfavorable near the magic angle, owing to the dominating influence of flavor polarization, such that the observed superconducting phase near the magic angle is always associated with an underlying Fermi surface, which preserves time-reversal symmetry. Accordingly, the illustrated twisted trilayer graphene 212 can use a twist angle between 1.2 and 1.4 degrees, well below the magic angle for twisted trilayer graphene.

FIG. 3 illustrates another example implementation 300 of the system of FIG. 1 utilizing a structure 310 formed from twisted trilayer graphene 312 and a layer of tungsten diselenide (WSe₂) 314. Like the twisted trilayer graphene 312 of FIG. 2, the illustrated twisted trilayer graphene 312 can use a twist angle between 1.2 and 1.4 degrees. In the illustrated implementation, each of the twisted trilayer graphene 312 and the layer of tungsten diselenide 314 is layered on and supported by a dielectric substrate 316, such as hexagonal boron nitride (HBN), that has been exfoliated to be atomically flat, such that the twisted trilayer graphene and the layer of tungsten diselenide are substantially encapsulated by the dielectric substrate. At the interface between the twisted trilayer graphene 312 and the layer of tungsten diselenide 314, a stable time-reversal symmetry breaking field associated with the interface is obtained, and a valley ferromagnetic state associated with the interface can be controlled via a magnetic field source 320 that provides an out-of-plane magnetic field to the interface. In particular, an out-of-plane magnetic field of between ten and one hundred millitesla, can be applied to the interface and then gradually reduced to zero to provide superconducting transport behavior in a specific direction, referred to herein as training the diode. To reverse the direction of the superconducting transport behavior, the same process can be applied with an out-of-plane magnetic field in an opposite direction, allowing the direction of superconducting transport associated with the diode to be selected via retraining of the diode with the appropriate magnetic field.

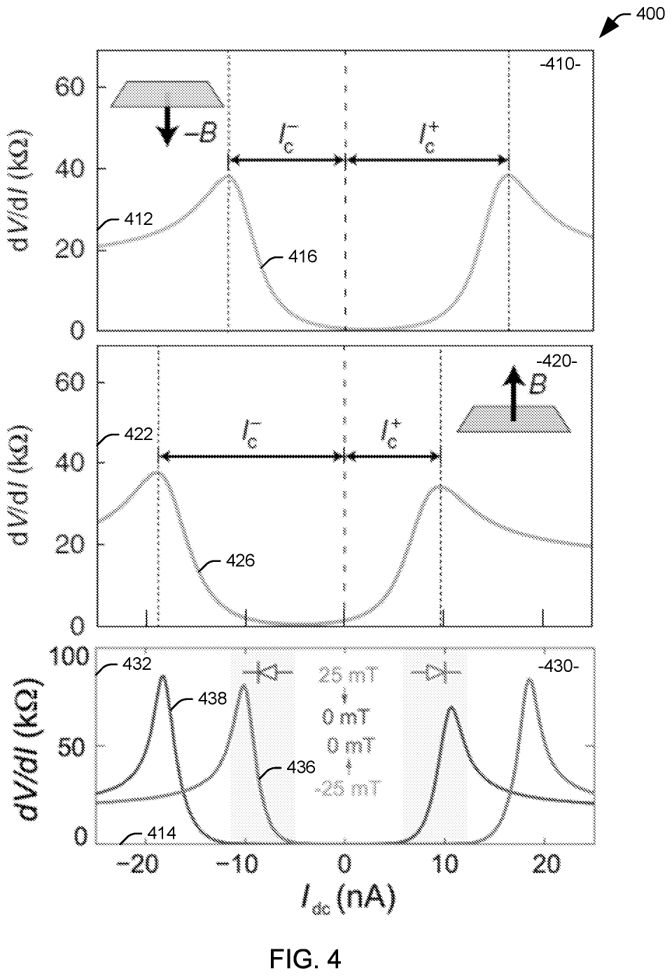

FIG. 4 is a diagram 400 illustrating the behavior of the superconducting diode formed by the structure 310 of FIG. 3 after training with the out-of-plane magnetic field. An upper portion 410 of the diagram represents training of the structure 310 using an out-of-plane magnetic field having a first direction, and a middle portion 420 of the diagram represents training of the structure 310 using an out-of-plane magnetic field having a second direction that is opposite to the first direction. A lower portion of the diagram illustrates the differential resistance as a function of the DC current in the absence of a magnetic field measured after training with a magnetic field. The vertical axis 412, 422, and 432 of each portion represents a differential resistance, measured in kiloohms, of the diode at with a displacement field of −573 mV/nm, a moiré filling fraction of 2.14, and a temperature of twenty millikelvin. The horizontal axis 414 represents a DC current, in nanoamps, with the differential resistance as a function of current shown as traces 416, 426, 436, and 438 forma each portion 410, 420, and 430.

In the upper portion 410, the trace 416 represents the differential resistance under an applied field of negative twenty-five millitesla. In the middle portion, the trace 426 represents the differential resistance under an applied field of twenty-five millitesla, In the lower portion 430, a first trace 436 represents the differential resistance under no applied magnetic field, but after training with a magnetic field of negative twenty-five millitesla, that is slowly ramped down to zero. Similarly, a second trace 438 represents the differential resistance under no magnetic field, but after training with a magnetic field of twenty-five millitesla, that is slowly ramped down to zero. When the magnetic field is reduced to zero from the applied negative twenty-five millitesla field illustrated in 410, the superconducting diode is trained in the forward direction. The sample exhibits zero resistance in the DC current range of +7 to +12 nA, but highly resistive at −7 to −12 nA. When the magnetic field is reduced to zero from the applied twenty-five millitesla field illustrated in 420, the superconducting phase behaves as a reverse bias. The sample is highly resistive in the DC current range of +7 to +12 nA, but exhibits zero resistance at −7 to −12 nA.

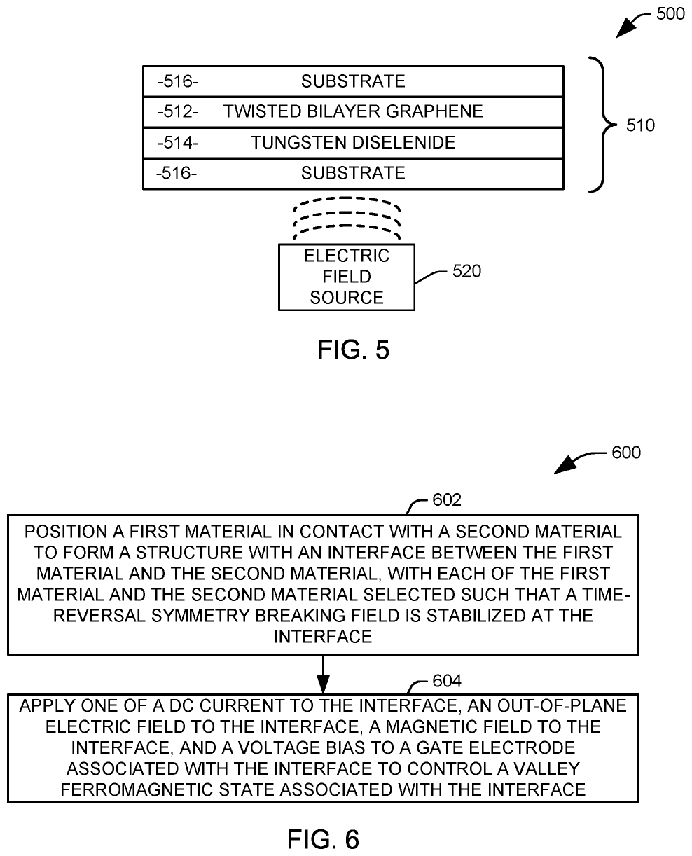

FIG. 5 illustrates an example implementation 500 of the system of FIG. 1 utilizing a structure 510 formed from twisted bilayer graphene 512 and a layer of tungsten diselenide (WSe₂) 514. In the illustrated implementation, each of the twisted bilayer graphene 512 and the layer of tungsten diselenide 514 is layered on and supported by a dielectric substrate 516, such as hexagonal boron nitride (HBN), that has been exfoliated to be atomically flat, such that the twisted bilayer graphene and the layer of tungsten diselenide are substantially encapsulated by the dielectric substrate. At the interface between the twisted bilayer graphene 512 and the layer of tungsten diselenide 514, a stable time-reversal symmetry breaking field associated with the interface is obtained, and a valley ferromagnetic state associated with the interface can be controlled via an applied electric field from an electric field source 520 to function as a memory. In one example, the electric field is generated by applying respective voltage biases to gate electrodes on opposing sides of the structure 510. Through application of the electric field, the ferromagnetic state can be changed to store a bit or to read out a bit previously stored.

In view of the foregoing structural and functional features described above in FIGS. 1-5, an example method will be better appreciated with reference to FIG. 6. While, for purposes of simplicity of explanation, the method of FIG. 6 is shown and described as executing serially, it is to be understood and appreciated that the present invention is not limited by the illustrated order, as some actions could in other examples occur in different orders and/or concurrently from that shown and described herein.

FIG. 6 illustrates an example of a method 600 for fabricating an assembly that uses a stabilized time-reversal symmetry breaking field to provide a desired function. At 602, a first material is positioned in contact with a second material to form a structure with an interface between the first material and the second material. Each of the first material and the second material are selected such that a time-reversal symmetry breaking field is stabilized at the interface. In one example, the first material is twisted multi-layer graphene and the second material is a transition metal dichalcogenide, such as tungsten diselenide. In one implementation, a first substrate, formed from a dielectric material, is exfoliated to provide an atomically flat surface, and the first material is applied to the surface of the first substrate. A second substrate, formed from the dielectric material, is exfoliated to provide an atomically flat surface, and the second material is applied to the surface of the second substrate, and the first material and the second material are positioned such that the first material and the second material are substantially encapsulated by the dielectric material.

At 604, either a DC current is applied to the interface, an out-of-plane electric field is applied to the interface, a magnetic field is applied to the interface, or a voltage bias is applied to a gate electrode associated with the interface, to control a valley ferromagnetic state associated with the interface. In one example, a magnetic field having a direction out of a plane associated with the interface is applied to provide a superconducting diode having a direction of current flow for which superconducting transport behavior is exhibited. Specifically, the magnetic field can be used to train the direction of superconducting transport behavior of the diode, with a direction of current flow selected for which superconducting transport behavior is desired, a direction for the magnetic field selected to provide the selected direction of current flow, and the magnetic field applied in the selected direction. In one example, the training is performed by applying the magnetic field at a predetermined magnitude and gradually reducing the magnitude of the magnetic field to zero. The training can be undone by passing a current of sufficient intensity through the diode.

In another example, a voltage bias to the gate to provide a superconducting diode having a direction of current flow for which superconducting transport behavior is exhibited. The specific voltage bias applied to the gate associated with the interface can be used to initialize, or train, the diode, as well as to dynamically change the direction of superconducting transport behavior associated with the diode. In a further example, the first material is twisted bilayer graphene, and the assembly provides a memory. In this example, the applied DC current, electric field, magnetic field, or gate bias can be used to store a bit within the structure or read a bit stored within the structure.

What have been described above are examples of the present invention. It is, of course, not possible to describe every conceivable combination of components or methodologies for purposes of describing the present invention, but one of ordinary skill in the art will recognize that many further combinations and permutations of the present invention are possible. While certain novel features of this invention shown and described below are pointed out in the annexed claims, the invention is not intended to be limited to the details specified, since a person of ordinary skill in the relevant art will understand that various omissions, modifications, substitutions and changes in the forms and details of the invention illustrated and, in its operation, may be made without departing in any way from the spirit of the present invention. Accordingly, the present invention is intended to embrace all such alterations, modifications, and variations that fall within the scope of the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements. No feature of the invention is critical or essential unless it is expressly stated as being “critical” or “essential.”

What is claimed is:

1. An assembly comprising:
a structure comprising a layer of a first material positioned in contact with a layer of a second material to form an interface between the first material and the second material, each of the first material and the second material being selected such that a time-reversal symmetry breaking field associated with the interface is stabilized; and
a control apparatus associated with the structure configured to control a ferromagnetic state associated with the interface.

2. The assembly of claim 1, wherein the control apparatus comprises one of a current source configured to provide a DC current, a gate electrode connected to a gate voltage source and configured to apply field effect gating to the interface, an electric field source configured to apply an out-of-plane electric field to the interface, and a magnetic field source configured to apply an out-of-plane magnetic field to the interface.

3. The assembly of claim 1, wherein one of the first material and the second material is twisted multi-layer graphene and an other of the first material and the second material is a transition metal dichalcogenide.

4. The assembly of claim 3, wherein the one of the first material and the second material is twisted trilayer graphene, and the structure and the control apparatus are configured to provide a superconducting diode having a direction of current flow for which superconducting transport behavior is exhibited.

5. The assembly of claim 4, wherein the control interface comprises the gate electrode connected to the gate voltage source and configured to apply field effect doping to the interface to select a direction of current flow for which superconducting transport behavior is exhibited for the superconducting diode.

6. The assembly of claim 4, wherein the control interface comprises the magnetic field source configured to apply the out-of-plane magnetic field to the interface, the magnetic field source being configured to apply the out-of-plane magnetic field with a predetermined amplitude to the interface and gradually decrease the amplitude of the out-of-plane magnetic field to zero.

7. The assembly of claim 3, wherein the one of the first material and the second material is twisted bilayer graphene, and the structure is configurable via the control apparatus to store a bit within the structure.

8. The assembly of claim 3, wherein the one of the first material and the second material is twisted bilayer graphene, and the structure is configurable via the control apparatus to read a bit stored within the structure.

9. The assembly of claim 3, wherein the transition metal dichalcogenide is tungsten diselenide.

10. A method for fabricating an assembly, the method comprising:
positioning a first material in contact with a second material to form a structure with an interface between the first material and the second material, each of the first material and the second material being selected such that a time-reversal symmetry breaking field is stabilized at the interface; and
applying one of a DC current to the interface, an out-of-plane electric field to the interface, a magnetic field to the interface, and a voltage bias to a gate electrode associated with the interface to control a valley ferromagnetic state associated with the interface.

11. The method of claim 10, wherein one of the first material and the second material is twisted multi-layer graphene and an other of the first material and the second material is a transition metal dichalcogenide.

12. The method of claim 11, wherein applying the one of the DC current to the interface, the out-of-plane electric field to the interface, the magnetic field to the interface, and the voltage bias to the gate electrode associated with the interface comprises applying the magnetic field to the interface, the magnetic field having a direction out of a plane associated with the interface to provide a superconducting diode having a direction of current flow for which superconducting transport behavior is exhibited.

13. The method of claim 11, wherein applying the magnetic field to the interface comprises applying the magnetic field at a predetermined magnitude and gradually reducing the magnitude of the magnetic field to zero.

14. The method of claim 11, further comprising:
selecting a direction of current flow for the superconducting diode for which superconducting transport behavior is desired;
selecting a direction for the magnetic field that will provide the superconducting diode with the selected direction of current flow exhibiting superconducting transport behavior; and
applying the magnetic field to the interface in the selected direction to provide a superconducting diode with the selected direction of current flow exhibiting superconducting transport behavior.

15. The method of claim 11, wherein applying the one of the DC current to the interface, the out-of-plane electric field to the interface, the magnetic field to the interface, and the voltage bias to a gate electrode associated with the interface comprising applying the voltage bias to the gate to provide a superconducting diode having a direction of current flow for which superconducting transport behavior is exhibited.

16. The method of claim 11, wherein the one of the first material and the second material is twisted bilayer graphene, and applying the one of the DC current to the interface, the out-of-plane electric field to the interface, the magnetic field to the interface, and the voltage bias to the gate electrode associated with the interface stores a bit within the structure.

17. The method of claim 11, wherein the one of the first material and the second material is twisted bilayer graphene, and applying the one of the DC current to the interface, the out-of-plane electric field to the interface, the magnetic field to the interface, and the voltage bias to the gate electrode associated with the interface reads a bit stored within the structure.

18. The method of claim 10, further comprising:
exfoliating a surface of a first substrate formed from a dielectric material to provide an atomically flat surface;
applying the first material to the surface of the first substrate;
exfoliating a surface of a second substrate formed from the dielectric material to provide an atomically flat surface; and
applying the second material to the second substrate;
wherein the first material and the second material are positioned such that the first material and the second material are substantially encapsulated by the dielectric material.

19. A superconducting diode assembly comprising:
a structure comprising a transition metal dichalcogenide layered on twisted trilayer graphene to form an interface having a stabilized time-reversal symmetry breaking field; and
a control apparatus associated with the structure configured to apply a magnetic field to the interface to provide a structure that exhibits superconducting transport behavior when current flows in one direction and exhibits significant resistance when current flows in the opposite direction.

20. The superconducting diode assembly of claim 19, wherein the transition metal dichalcogenide is tungsten diselenide.
